(19) United States
(12) Patent Application Publication
(10) Pub. No.: US 2011/0215072 A1
(43) Pub. Date: Sep. 8, 2011

(54) PLASMA APPARATUS HAVING A CONTROLLER FOR CONTROLLING A PLASMA CHAMBER AND METHODS FOR CONTROLLING THE PLASMA APPARATUS

(76) Inventors: Sangwuk PARK, Osan-si (KR); Kye Hyun Baek, Suwon-si (KR); Yongjin Kim, Suwon-si (KR); Ho Ki Lee, Anyang-si (KR); Sooyeon Jeong, Bucheon-si (KR); GeumJung Seong, Seoul (KR)

(21) Appl. No.: 13/041,810

(22) Filed: Mar. 7, 2011

(30) Foreign Application Priority Data
Mar. 8, 2010 (KR) 10-2010-0020501

(51) Int. Cl. H05H 1/00; C23C 14/34; C23C 14/54

(52) U.S. Cl. 216/67; 204/192.1; 427/535

(57) ABSTRACT

Provided is a method for controlling a plasma apparatus. The method includes measuring a plasma spectrum in a plasma chamber by an optical emission spectroscopy, setting a baseline of the measured plasma spectrum, normalizing the measured plasma spectrum by dividing a value of the measured plasma spectrum by a value of the baseline, and controlling the plasma chamber by setting parameters of a plasma process using the normalized plasma spectrum. A plasma apparatus is also provided.

### BACKGROUND

1. Field

Embodiments relate to plasma apparatus and methods for controlling the plasma apparatus. More specifically, the embodiment relates to plasma apparatus having a controller for controlling a plasma chamber and methods for controlling the plasma apparatus.

2. Description of the Related Art

Plasma is used in some unit processes to fabricate a semiconductor device or a liquid crystal display (LCD) device. The unit processes may comprise an etching process, a deposition process, and a sputtering process. In general, plasma is generated inside a predetermined vacuum container (i.e., a plasma chamber) using a radio frequency. The unit processes utilize physical and/or chemical characteristics of ions and radicals included in the plasma.

In order to meet technical requirements associated with integration and performance of the semiconductor device, higher-level technologies have been applied to the unit processes. However, because reproducibility of a process or reproducibility of product performance are greatly affected even by a slight change associated with process conditions, there is a need to monitor and control slight changes associated with these process conditions.

There are various process conditions affecting the process reproducibility. Thus, the process reproducibility may not be easily stabilized by a method of monitoring the respective process conditions. For example, although some process parameters such as gas flow, unintentional fluctuation, chamber memory effect, arcing, and plasma instability affect reproducibility of a process and reproducibility of product performance, it is difficult to accurately measure all the process parameters and foresee variation of a process result from the measured result.

Undoubtedly, a process state may be monitored on the fact that characteristics of the unit processes using plasma are sensitive to a state of the plasma. For example, etching endpoint detection (EPD) may be achieved by measuring variation of optical characteristics of plasma. Specifically, because composition and pressure of gas inside a chamber vary when a layer is etched and removed to expose an underlying layer, the intensity of a specific-wavelength light emitted from the plasma may vary. The etching endpoint detection may be achieved by sensing variation in the intensity of the light. However, because this method uses variation in intensity of the specific-wavelength light, it may be used to detect the etching endpoint but cannot provide sufficient information on whether the process is reproducibly performed.

An optical emission spectroscopy (OES) is a very useful sensor capable of observing a plasma state in real time. Nonetheless, an aspect of plasma spectrum measured by the OES varies with the state of a viewport window of a plasma chamber, irrespective of a plasma state. Accordingly, there may be many limitations in use of the OES. The viewport window becomes cloudy with the increase of plasma process time, which is called a window cloud effect. The window cloud effect means that a material, i.e., a chemically synthesized polymer forms a thin film on a surface of the viewport window during the plasma process to reduce light transmittance of the viewport window. That is, the window cloud effect becomes noticeable with the increase of plasma process time to gradually reduce the light transmittance. Even when light passes viewport windows of the same state, its transmittance is variable due to its properties. If the states of the viewport window are different at two specific measurement points of time, a difference between spectrums measured at different measurement points of time cannot be analyzed or, although the difference can be analyzed, an error becomes greater due to properties of the OES using information on light intensity of each wavelength.

### SUMMARY

Embodiments are therefore directed to a plasma apparatus and methods for controlling the plasma apparatus, which substantially overcome one or more of the problems due to the limitations and disadvantages of the related art.

It is therefore a feature of an embodiment to provide a method for controlling the plasma apparatus to improve reproducibility and accuracy of the plasma process.

It is therefore another feature of an embodiment to provide a plasma apparatus to improve reproducibility and accuracy of the plasma process.

At least one of the above and other features and advantages may be realized by providing a method for controlling a plasma apparatus. The method may include measuring a plasma spectrum in a plasma chamber using an optical emission spectroscopy, setting a baseline of the measured plasma spectrum, normalizing the measured plasma spectrum by dividing a value of the measured plasma spectrum by a value of the baseline, and controlling the plasma chamber by setting parameters of a plasma process using the normalized plasma spectrum.

According to example embodiments, setting a baseline of the measured plasma spectrum may include selecting valleys of the measured plasma spectrum and forming the baseline to connect the valleys.

According to example embodiments, selecting valleys may include selecting local minimums by primary differentiation of the measured plasma spectrum. Selecting local minimums may include selecting respective smallest values within wavelength bands over a predetermined range of the measured plasma spectrum.

According to example embodiments, forming the baseline may include connecting the valleys by means of interpolation. The interpolation may include at least one selected from the group consisting of linear interpolation, polynomial interpolation, and spline interpolation.

According to example embodiments, controlling the plasma chamber may include modifying a recipe of the plasma process.

According to example embodiments, the method may further include selecting inflection points by secondary differentiation of the measured plasma spectrum and calculating and normalizing an area between the inflection points.

According to example embodiments, a flow rate of gas for use in the plasma process may be determined using the area between the inflection points.

According to example embodiments, measuring a plasma spectrum in a plasma chamber by an optical emission spectroscopy may include measuring the plasma spectrum through a viewport window of the plasma chamber.

At least one of the above and other features and advantages may also be realized by providing a plasma apparatus. The plasma apparatus may include a plasma chamber having a viewport window, an optical emission spectroscopy configured to measure a plasma spectrum in the plasma chamber through the viewport window, a signal processor configured to process and normalize a signal of the measured plasma spectrum, and a controller configured to control the plasma chamber by setting parameters of a plasma process using the normalized plasma spectrum. In the system, processing and normalizing a signal of the measured plasma spectrum may include setting a baseline of the measured plasma spectrum and dividing a value of the measured plasma spectrum by a value of the baseline.

According to example embodiments, setting a baseline of the measured plasma spectrum may include selecting valleys of the measured plasma spectrum and forming the baseline to connect the valleys.

According to example embodiments, selecting valleys may include selecting local minimums by primary differentiation of the measured plasma spectrum. Selecting local minimums may include selecting respective smallest values within wavelength bands over a predetermined range of the measured plasma spectrum.

According to example embodiments, forming the baseline may include connecting the valleys by means of interpolation. The interpolation may include at least one selected from the group consisting of linear interpolation, polynomial interpolation, and spline interpolation.

According to example embodiments, the plasma apparatus may further include selecting inflection points by secondary differentiation of the measured plasma spectrum and calculating and normalizing an area between the inflection points.

According to example embodiments, a flow rate of gas for use in the plasma process may be determined using the area between the inflection points.

According to example embodiments, the controller may include an analysis program for quantitatively analyzing the normalized plasma spectrum.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a configuration diagram of a system for controlling a plasma apparatus according to an embodiment of the inventive concept;

FIGS. 2 and 3 illustrate flowcharts of a method for controlling a plasma apparatus according to an embodiment of the inventive concept;

FIGS. 4A to 7B illustrate graphic diagrams of a method for controlling a plasma apparatus according to embodiments of the inventive concept; and

FIG. 8 illustrates a graphic diagram of a method for controlling a plasma apparatus according to another embodiment of the inventive concept.

### DETAILED DESCRIPTION

Korean Patent Application No. 10-2010-0020501, filed on Mar. 8, 2010, in the Korean Intellectual Property Office, and entitled: “Plasma Apparatus Having a Controller for Controlling a Plasma Chamber and Methods for Controlling the Plasma Apparatus,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

Additionally, the embodiment in the detailed description will be described with sectional views as ideal exemplary views of the inventive concept. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concept.

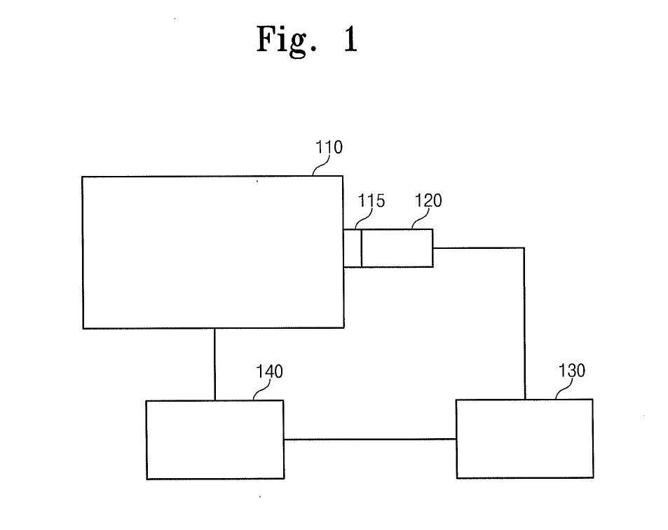

FIG. 1 is a configuration diagram illustrating a plasma apparatus according to an embodiment of the inventive concept. As illustrated, the apparatus includes a plasma chamber 110 in which plasma is generated, a viewport window 115 configured to view the inside of the plasma chamber 110, an optical emission spectroscopy (OES) 120 configured to measure a plasma spectrum in the plasma chamber 110, a signal processor 130 configured to process and normalize a signal of the plasma spectrum measured by the OES 120, and a controller 140 configured to control the plasma chamber 110 by setting process parameters using the normalized plasma spectrum.

The plasma chamber 110 may be an etching chamber outfitted to etch a wafer. However, the plasma chamber 110 according to the inventive concept is not limited to an etching chamber and may be one of chambers for use in deposition or sputtering processes. Moreover, the plasma chamber 110 according to the inventive concept is not limited to a chamber for manufacturing a semiconductor device and may be one of plasma chambers for use in various industrial applications such as manufacturing of a liquid crystal display (LCD).

The OES 120 may be connected to the viewport window 115 by an optical fiber (not shown) to measure optical characteristics of light emitted through the viewport window 115 from plasma in the plasma chamber 120.

Processing and normalizing a signal of plasma spectrum measured by the OES 120 at the signal processor 130 may include setting a baseline of the measured plasma spectrum and dividing values of the measured plasma spectrum by values of the baseline. The baseline may be a virtual self-background whose decay rate at the viewport window 115 of the plasma chamber 110 is identical to that of the measured plasma spectrum.

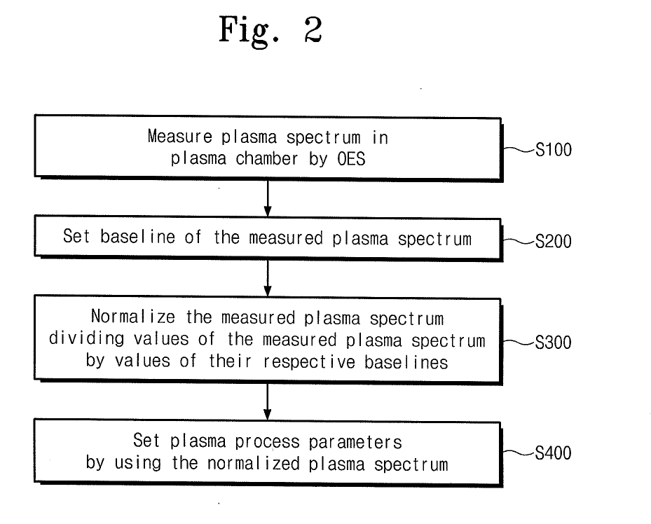

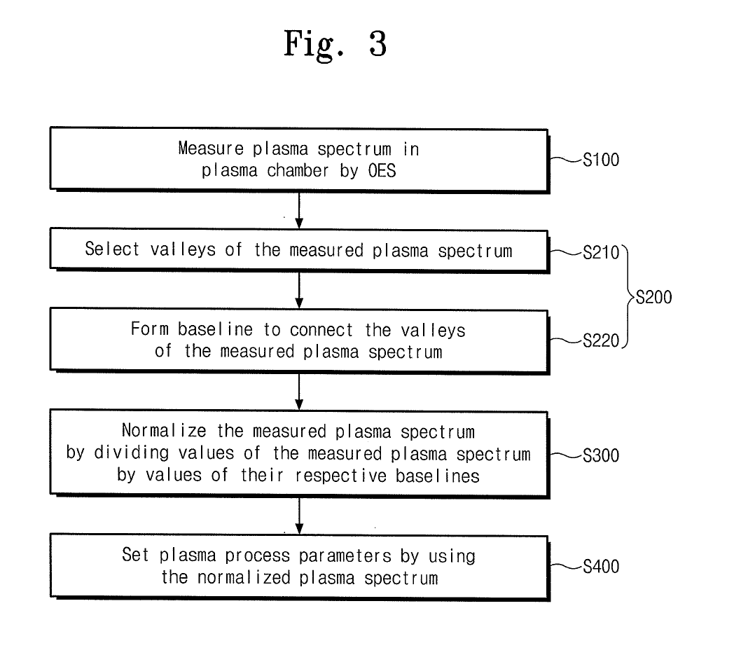

Setting the baseline of the measured plasma spectrum may include selecting valleys of the measured plasma spectrum and forming a baseline to connect the valleys. Selecting the valleys may be selecting local minimums by primary differentiation of the measured plasma spectrum. Selecting local minimums may be selecting respective smallest values within wavelength bands over a predetermined range of the measured plasma spectrum. Forming the baseline may be connecting the valleys by means of interpolation. The interpolation may include one selected from the group consisting of linear interpolation, polynomial interpolation, and spline or cubic interpolation. Processing and normalizing a signal of the measured plasma spectrum at the signal processor 130 will be described in detail later with reference to FIGS. 2 and 3.

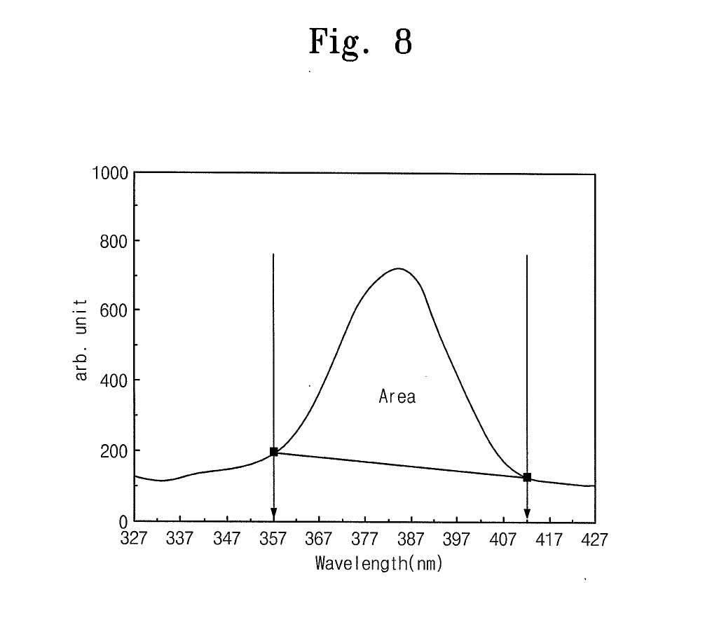

In addition, the signal processor 130 may calculate and normalize an area between selected adjacent inflection points by secondary differentiation of the measured plasma spectrum, which will be described in detail later with reference to FIG. 8.

Controlling the plasma chamber 110 using the controller 140 may be modifying a recipe of the plasma process. The recipe of the plasma process may include process time, gas flow rate, pressure, and temperature. In addition, the controller 140 may determine a gas flow rate of the plasma process using the normalized area between the inflection points.

The controller 140 may include an analysis program for quantitative analysis of the normalized plasma spectrum. The analysis program may be used to compare and analyze a plurality of normalized plasma spectrums. The analysis program may be a type of computer software.

The signal processor 130 and the controller 140 may be incorporated in a device such as a computer.

According to embodiments of the inventive concept, the plasma spectrum measured by the optical emission spectroscopy (OES) may be divided by the self-background to normalize the plasma spectrum. That is, the plasma apparatus according to embodiments of the inventive concept may include a control system to normalize the plasma spectrum measured by the optical emission spectroscopy (OES). As a result, the plasma spectrum of the plasma generated in the chamber 110 may be quantitatively analyzed regardless of various external and internal factors. The control system may include the signal processor 130 and the controller 140. The control system may control the plasma chamber 110 by setting plasma process parameters from the normalized plasma spectrum. As a result, reproducibility of a plasma process may be improved. In addition, the measured plasma spectrum is normalized using the self-background having the same decay rate as the measured plasma spectrum as described above. Thus, unlike a conventional method using an actinometry technique to obtain a reference value, the control system according to the inventive concept may reduce an error range to an overall plasma spectrum.

Moreover, the control system of the plasma apparatus according to embodiments of the inventive concept may normalize the plasma spectrum measured by the optical emission spectroscopy (OES), thereby quantitatively analyzing the plasma spectrum irrespective of various external and internal factors, as mentioned above. Accordingly, the control system may perform quantitative comparison between plasma spectrums regarding different points of time, different plasma chambers, and different plasma conditions. As a result, plasma processes having different conditions may be compared and analyzed to improve accuracy of a plasma process. In addition, a plasma spectrum analysis system for use in various plasma-associated applications may be provided.

Furthermore, the control system of the plasma apparatus according to embodiments of the inventive concept may normalize the plasma spectrum measured by the optical emission spectroscopy (OES) using secondary differentiation of the measured plasma spectrum, thereby quantitatively analyzing the amount of ions and radicals included in plasma. Accordingly, the control system may control a flow rate of gas for use in a plasma process. As a result, reproducibility and accuracy of the plasma process may be improved.

FIGS. 2 and 3 are flowcharts illustrating a method for controlling a plasma apparatus according to an embodiment of the inventive concept.

Referring to FIGS. 1 to 3, a method for controlling a plasma apparatus includes measuring a plasma spectrum in a plasma chamber 110 using an optical emission spectroscopy (OES) 120 (S100), setting a baseline of the measured plasma spectrum (S200), normalizing the measured plasma spectrum by dividing values of the measured plasma spectrum by values of their respective baselines (S300), and setting plasma process parameters using the normalized plasma spectrum (S400).

Measuring the plasma spectrum in the plasma chamber 110 using the OES 120 (S100) may include measuring optical characteristics of light emitted from plasma in the plasma chamber 100 through a viewport window 115 using the OES 120.

Setting the baseline of the measured plasma spectrum (S200) may include selecting valleys of the measured plasma spectrum (S210) and forming the baseline to connect the valleys of the measured plasma spectrum (S220). The baseline may be a virtual self-background whose decay rate at the viewport window 115 of the plasma chamber 110 is identical to that of the measured plasma spectrum.

Selecting valleys of the measured plasma spectrum (S210) may include selecting local minimums by primary differentiation of the measured plasma spectrum. Selecting the local minimums may include selecting respective their smallest values within wavelength bands over a predetermined range of the measured plasma spectrum.

Forming the baseline to connect the valleys of the measured plasma spectrum (S220) may include connecting the valley by means of interpolation. The interpolation may include one selected from the group consisting of linear interpolation, polynomial interpolation, and spline interpolation.

That is, setting the baseline of the measured plasma spectrum (S200) may include removing meaningless peaks at the measured plasma spectrum, setting valley for meaningful peaks at the measured plasma spectrum, and connecting the valleys to determine the resolution of the baseline.

At the step of normalizing the measured plasma spectrum by dividing values of the measured plasma spectrum by values of their respective baselines (S300), the plasma spectrum is numerically processed using a self-background. Therefore, the measured plasma spectrum may be quantitatively normalized irrespective of external factors such as a state of the viewport window 115 and an optical fiber connection state between the viewport window 115 and the OES 120 and internal factors such as a wall state of a plasma chamber, pressure, temperature, and measurement point of time.

Setting plasma process parameters by using the normalized plasma spectrum (S400) may be analyzing the normalized plasma spectrum to determine a recipe of the plasma process.

A method for controlling a plasma apparatus according to embodiments of the inventive concept may normalize a plasma spectrum in a plasma chamber measured by an optical emission spectroscopy (OES) by dividing the measured plasma spectrum by a self-background, thereby quantitatively analyzing the plasma spectrum in the plasma chamber irrespective of various external and internal factors. Accordingly, the method may control the plasma chamber by setting plasma process parameters from the normalized plasma spectrum. As a result, reproducibility of a plasma process may be improved. In addition, since the measured plasma spectrum is normalized using a self-background having the same decay rate as the measured plasma spectrum, unlike a conventional method for obtaining a reference value (e.g., actinometry method), a method for controlling a plasma apparatus with a smaller error to an overall plasma spectrum may be provided.

Moreover, a method for controlling a plasma apparatus according to embodiments of the inventive concept may normalize a plasma spectrum in a plasma chamber measured by an optical emission spectroscopy (OES) by dividing the measured plasma spectrum by a self-background, thereby quantitatively analyzing the plasma spectrum in the plasma chamber irrespective of various external and internal factors. Accordingly, the method may perform quantitative comparison between plasma spectrums regarding different points of time, different plasma chambers, and different plasma conditions. As a result, plasma processes having different conditions may be compared and analyzed to improve accuracy of a plasma process. In addition, a plasma spectrum analysis method for use in various plasma-associated applications may be provided.

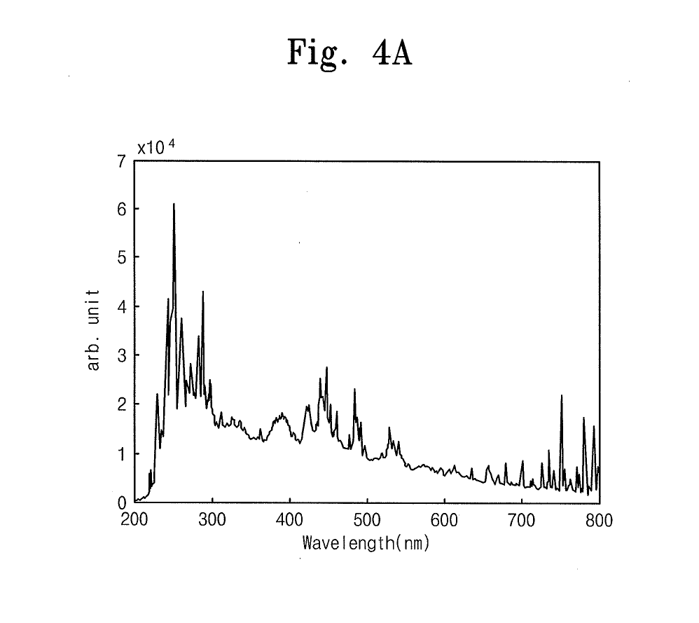

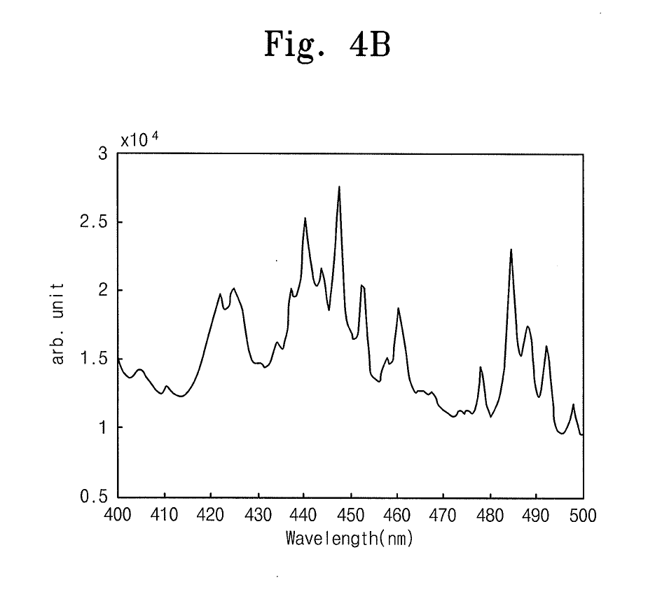

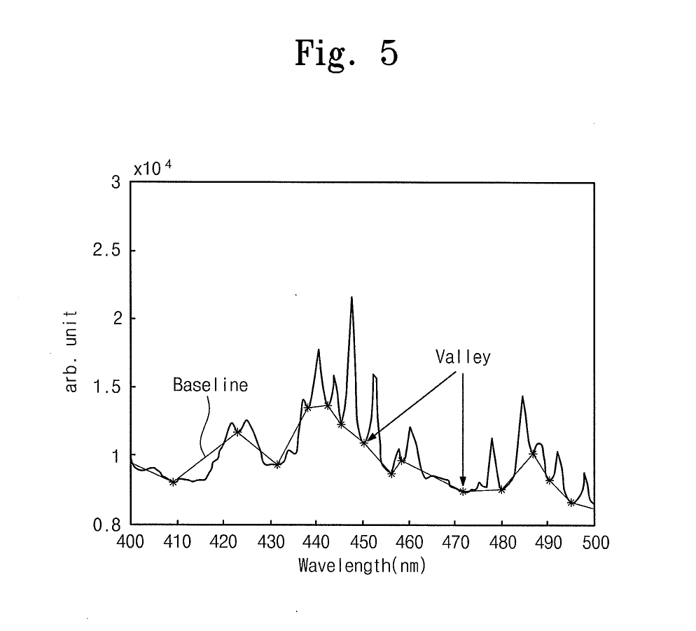

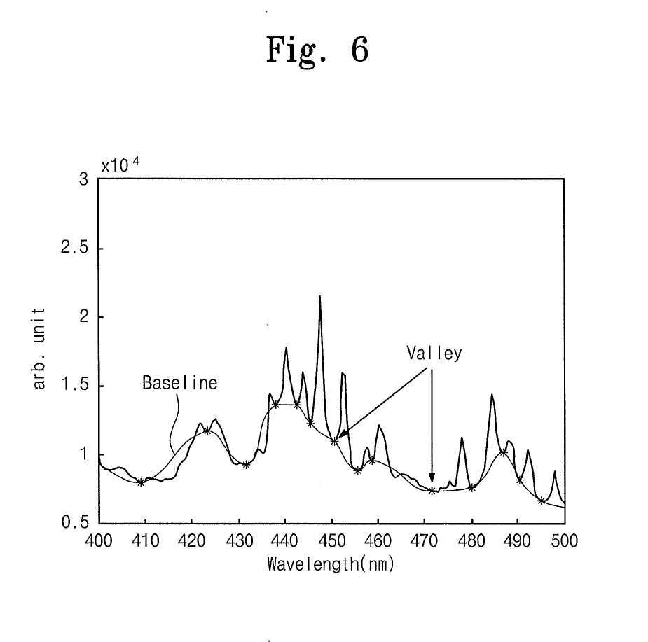

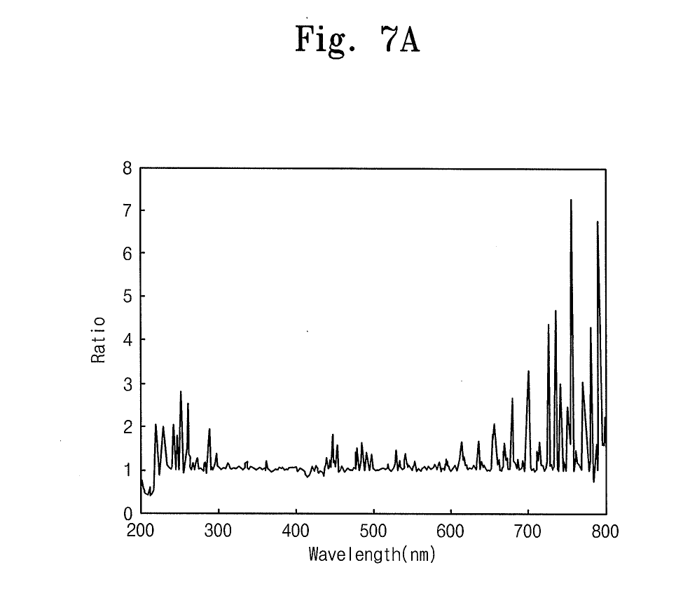

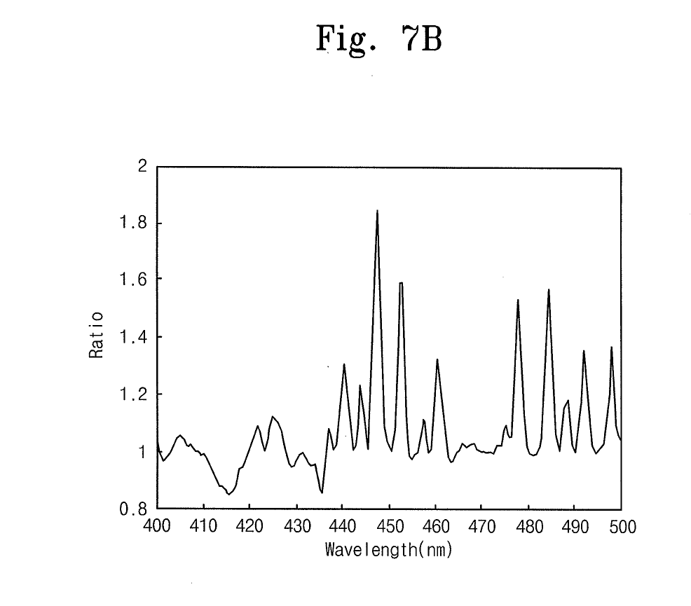

FIGS. 4A to 7B are graphic diagrams illustrating a method for controlling a plasma apparatus according to embodiments of the inventive concept. FIGS. 4B and 7B are enlarged graphic diagrams of portions in FIGS. 4A and 7A, respectively. FIGS. 5 and 6 are graphic diagrams corresponding to FIG. 4B.

Referring to FIGS. 4A and 4B, there are shown graphs of a plasma spectrum in plasma chamber measured by an optical emission spectroscopy (OES) through a viewport window of the plasma chamber. The plasma spectrum exhibits various shapes depending on external factors such as a state of the viewport window and an optical fiber connection state between the viewport window and the OES and internal factors such as a wall state of a plasma chamber, pressure, temperature, and measurement point of time.

Referring to FIGS. 5 and 6, there are shown graphs illustrating that a baseline is set from a measured plasma spectrum by means of linear interpolation and spline interpolation, respectively.

Valleys of a measured plasma spectrum are selected. The valleys may be local minimums obtained by primary differentiation of the measured plasma spectrum. Selecting local minimums may be selecting respective their smallest values within wavelength bands over a predetermined range of the measured plasma spectrum, which may be determining the resolution of a baseline to be set. The baseline may be a virtual self-background whose decay rate at the viewport window of a plasma chamber is identical to that of the measured plasma spectrum.

A baseline is formed to connect the valleys of the measured plasma spectrum. Forming a baseline may be connecting the valleys by means of interpolation. The interpolation used in FIG. 5 is linear interpolation, and the interpolation used in FIG. 6 is spline interpolation.

A value of the baseline varies with interpolations used. That is, normalization of measured plasma spectrum may become clearer using interpolation suitable for analysis of the measured plasma spectrum.

Although not shown, setting a baseline may be done by means of another interpolation such as, for example, polynomial interpolation.

Referring to FIGS. 7A and 7B, there are shown graphs of a plasma spectrum normalized by dividing a value of measured plasma spectrum by a value of a baseline.

A measured plasma spectrum is normalized by dividing values of the measured plasma spectrum by respective their values of a baseline. Since the measured plasma spectrum is numerically processed using a baseline that is a self-background, it may be quantitatively normalized irrespective of external factors such as a state of a viewport window and an optical fiber connection state between the viewport window and an optical emission spectroscopy (OES) and internal factors such as a wall state of a plasma chamber, pressure, temperature, and measurement point of time.

A plasma chamber is controlled by setting parameters of a plasma process through quantitative analysis of normalized plasma spectrum to improve reproducibility of the plasma process.

FIG. 8 is a graphic diagram illustrating a method for controlling a plasma apparatus according to another embodiment of the inventive concept.

Referring to FIG. 8, there is shown a graph illustrating that inflection points are selected by secondary differentiation of a plasma spectrum in a plasma chamber measured by an optical emission spectroscopy (OES) through a viewport window of the plasma chamber.

An area between selected adjacent inflection points may be calculated and normalized by secondary differentiation of the measured plasma spectrum. The area between inflection points may correspond to the quantitized amount to ions and radicals included in plasma. A flow rate of gas for use in a plasma process may be determined using the amount of ions and radicals included in quantitized plasma.

According to this embodiment, a plasma spectrum in a plasma chamber measured by an optical emission spectroscopy (OES) is secondarily differentiated and normalized to quantitatively analyze the amount of ions and radicals included in plasma. Thus, a flow rate of gas for use in a plasma process may be controlled to improve reproducibility and accuracy of the plasma process.

While the inventive concept has been described with reference to exemplary embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

1. A method for controlling a plasma apparatus, comprising:
measuring a plasma spectrum in a plasma chamber using an optical emission spectroscopy;
setting a baseline of the measured plasma spectrum;
normalizing the measured plasma spectrum by dividing a value of the measured plasma spectrum by a value of the baseline; and
controlling the plasma chamber by setting parameters of a plasma process using the normalized plasma spectrum.

2. The method as claimed in claim 1, wherein setting the baseline of the measured plasma spectrum comprises:
selecting valleys of the measured plasma spectrum; and
forming the baseline to connect the valleys.

3. The method as claimed in claim 2, wherein selecting the valleys comprises selecting local minimums by primary differentiation of the measured plasma spectrum.

4. The method as claimed in claim 3, wherein selecting the local minimums comprises selecting respective smallest values within wavelength bands over a predetermined range of the measured plasma spectrum.

5. The method as claimed in claim 2, wherein forming the baseline comprises connecting the valleys by means of interpolation.

6. The method as claimed in claim 5, wherein the interpolation includes at least one selected from the group consisting of linear interpolation, polynomial interpolation, and spline interpolation.

7. The method as claimed in claim 1, wherein controlling the plasma chamber comprises modifying a recipe of the plasma process.

8. The method as claimed in claim 1, further comprising:
selecting inflection points by secondary differentiation of the measured plasma spectrum; and
calculating and normalizing an area between the inflection points.

9. The method as claimed in claim 8, wherein a flow rate of gas for use in the plasma process is determined using the area between the inflection points.

10. The method as claimed in claim 1, wherein measuring the plasma spectrum in the plasma chamber using the optical emission spectroscopy comprises measuring the plasma spectrum through a viewport window of the plasma chamber.

11.-20. (canceled)
